(19) United States
(12) Patent Application Publication
(10) Pub. No.: US 2004/0066317 A1
(43) Pub. Date: Apr. 8, 2004

(54) Photo self-luminescent glowing phosphorous resin computer key caps

(76) Inventor: Hakeem Al-Raheem, Turlock, CA (US)

Correspondence Address: HAKEEM Al-RAHEEM, 2246 Typhoon Court, Turlock, CA, 95380, US

(21) Appl. No.: 10/264,824

(22) Filed: Oct. 5, 2002

(51) Int. Cl. H03M 11/00; H03K 17/94

(52) U.S. Cl. 341/22

(57) ABSTRACT

The present invention relates to the uses of photo luminescent glowing key caps, providing human beings luminescent lighting while using standard conventional computer key cap(s) in low lighting or in darkness without requiring any internal electrical component(s), circuit(s) or power(s). This includes the using of photo luminescent glowing phosphorus resin computer key caps in the form(s) and shape(s) of a standard QWERTY computers keyboard key cap(s).

Photo self-luminescent glowing phosphorous resin computer key caps.

### 2. DESCRIPTION OF THE FIGURE(S) OF THE DRAWING

Any broken line illustration of environmental structure in the drawing is not part of the design sought to be patented.

FIG. 1 is a front elevation superior view of a three-dimensional graphical art representing a conventional standard computer keyboard with key caps.

FIG. 2 is an enlarged front elevation superior view of a three-dimensional graphical art image representing of the said photo luminescent glowing conventional standard computer key caps.

FIG. 2—image 1 is an enlarged front elevation superior view of a three-dimensional graphical art representing of the said photo luminescent glowing conventional computer keyboard key cap superior surface.

FIG. 2—image 2 is an enlarged front elevation superior view of a three-dimensional graphical art representing of the said photo luminescent glowing conventional computer keyboard key cap lower base.

FIG. 3 is an enlarged lateral view of a three-dimensional graphical art mirror image representing of the said photo luminescent glowing conventional standard computer key cap including in mirror images 1, 2 from FIG. 2.

FIG. 3—image 1 is an enlarged lateral view of a three-dimensional graphical art representing of the said photo luminescent glowing conventional computer keyboard key cap superior surface.

FIG. 3—image 2 is an enlarged lateral view of a three-dimensional graphical art representing of the said photo luminescent glowing conventional computer keyboard key cap lower base.

### 3. FEATURE DESCRIPTION

### BACKGROUND OF THE INVENTION

The present invention relates to the uses of photo luminescent glowing phosphorous resin computer key caps. Photo luminescent phosphorus is a self-luminescent resin material capable of absorbing photons of light, and emits self-luminescent glow lighting without requiring any internal electrical component(s), circuit(s) or power(s). The said key cap(s) with photo luminescent glowing phosphorous resin shaped in the form of conventional computer QWERTY key cap(s), would enhance human beings sight while reading computer key cap(s) in low lighting or in darkness.

### SUMMARY OF THE INVENTION

More specifically, the present invention relates to computer keyboards having self-illuminated glowing phosphorous resin key caps.

The photo luminescent glowing phosphorous resin computer key caps, will provide self-luminescent lighting. The photo luminescent glowing phosphorous resin key cap(s) will absorb and store the energy of various ultraviolet and visible light and release the energy in way of visible lighting in dark environment or in the dark without any internal electrical component(s), circuit(s) or power(s). The light absorption and release processes are automatically completed and repeated ceaselessly.

### DESCRIPTION OF THE PREFERRED EMBODIMENT

The disclosure contains several different embodiments according to this invention. Where appropriate, like components or features will be referenced with the same numeral. To avoid redundant discussion, only different or distinct features of one embodiment as compared to another embodiment will be discussed in detail.

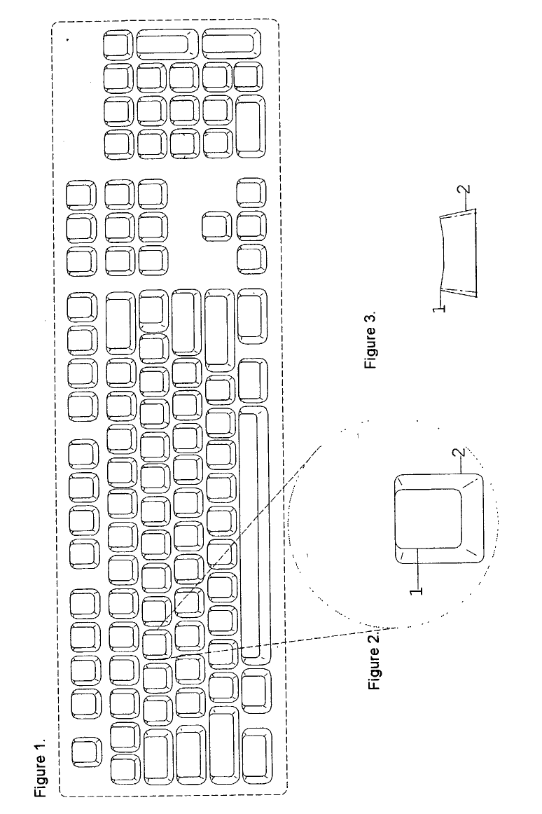

The said photo luminescent glowing phosphorous membrane resin key cap(s) is in the plurality form and shape of the said standard QWERTY computer keyboard key cap(s) as shown in FIG. 1, 2 and 3.

Field of Search 341/20,22,23 400/493,485,486 200/308,310,312,512 345/170,173

U.S. Patent Documents

| | | | |
|---|---|---|---|
| 4527250 | July, 1985 | Galdun | 341/23. |
| 4823311 | April, 1989 | Hunter | 341/23. |
| 4853888 | August, 1989 | Cata | 345/172. |
| 5144303 | September, 1992 | Purcell | 341/23. |
| 5166683 | November, 1992 | McKay | 341/23. |
| 5181029 | January, 1993 | Kim. | |
| 5382777 | January, 1995 | Yuhara | 235/379. |
| 5491495 | February, 1996 | Ward | 345/173. |
| 5510809 | April, 1996 | Sakai | 345/140. |
| 5515045 | May, 1996 | Tak | 341/23. |
| 5594471 | January, 1997 | Deeran | 345/173. |
| 5617343 | April, 1997 | Danielson | 395/200. |
| 5650605 | July, 1997 | Morioka | 235/379. |
| 4320268 | March, 1982 | Brown | 200/5. |
| 4811175 | March, 1989 | DeSmet | 362/95. |

I (we) claim the following:

1. The photo luminescent glowing phosphorous resin key cap(s), is self-emitting in the plurality form(s) and shape(s) of every standard conventional QWERTY computer keyboard key cap(s) therein.
